(19) United States
(12) Patent Application Publication
(10) Pub. No.: US 2023/0299078 A1
(43) Pub. Date: Sep. 21, 2023

(54) SEMICONDUCTOR DEVICE

(71) Applicant: FUJI ELECTRIC CO., LTD., Kanagawa (JP)

(72) Inventor: Soichi YOSHIDA, Matsumoto-city (JP)

(21) Appl. No.: 18/320,997

(22) Filed: May 21, 2023

Related U.S. Application Data
(63) Continuation of application No. PCT/JP2022/018987, filed on Apr. 26, 2022.

(30) Foreign Application Priority Data
Jun. 18, 2021 (JP) 2021-101987

(51) Int. Cl. H01L 27/06; H01L 29/32; H01L 29/40; H01L 29/861; H01L 29/739

(52) U.S. Cl. CPC H01L 27/0664; H01L 29/32; H01L 29/407; H01L 29/8613; H01L 29/7397

(57) ABSTRACT

There is provided a semiconductor device that includes a transistor portion and a diode portion, the semiconductor device including a drift region, a base region, an emitter region, and a plurality of trench portions, in which the transistor portion has a boundary region provided to be adjacent to the diode portion, a lifetime control region is provided from the diode portion, across the boundary region, to the transistor portion provided with the emitter region, in an array direction of the plurality of trench portions, the boundary region has a plug region of a second conductivity type which is provided to extend in an extension direction of the plurality of trench portions and which has a doping concentration higher than that of the base region, and a contact region and the base region are alternately arranged in the extension direction, at a front surface in the boundary region.

The contents of the following Japanese patent application(s) are incorporated herein by reference:
NO. 2021-101987 filed in JP on Jun. 18, 2021
NO. PCT/JP2022/018987 filed in WO on Apr. 26, 2022

### BACKGROUND

### 1. Technical Field

The present invention relates to a semiconductor device.

### 2. Related Art

A semiconductor device including a transistor portion and a diode portion is known (for example, refer to Patent Documents 1 and 2).
Patent Document 1: Japanese Patent Application Publication No. 2018-073911
Patent Document 2: International Publication No. WO 2019/176327

### Technical Problem

In a semiconductor device, it is preferable to reduce a reverse recovery loss Err.

### BRIEF DESCRIPTION OF THE DRAWINGS

FIG. 1A shows an example of a top plan view of a semiconductor device 100.

FIG. 1B shows an example of a cross section a-a′ of the semiconductor device 100 in FIG. 1A.

FIG. 1C shows an example of a cross section b-b′ of the semiconductor device 100 in FIG. 1A.

FIG. 1D shows an example of a cross section c-c′ of the semiconductor device 100 in FIG. 1A.

FIG. 2 shows a modification example of the semiconductor device 100.

FIG. 3 shows a modification example of the semiconductor device 100.

FIG. 4 shows a modification example of the semiconductor device 100.

FIG. 5 shows a semiconductor device 500 of a comparison example.

FIG. 6A shows examples of IV characteristics of the semiconductor device 100 and the semiconductor device 500.

FIG. 6B shows examples of reverse recovery characteristics of the semiconductor device 100 and the semiconductor device 500.

FIG. 7 shows a relationship between a thinning rate [%] and a change rate [%] of a reverse recovery loss Err.

### DESCRIPTION OF EXEMPLARY EMBODIMENTS

Hereinafter, the present invention will be described through embodiments of the invention, but the following embodiments do not limit the claimed invention. In addition, not all combinations of features described in the embodiment are essential to the solution of the invention.

In the present specification, one side in a direction parallel to a depth direction of a semiconductor substrate is referred to as an “upper” side, and the other side is referred to as a “lower” side. One surface of two principal surfaces of a substrate, a layer, or another member is referred to as an upper surface, and the other surface is referred to as a lower surface. “Upper”, “lower”, “front”, and “back” directions are not limited to a direction of gravity, or a direction of an attachment to a substrate or the like when a semiconductor device is mounted.

In the present specification, technical matters may be described by using orthogonal coordinate axes of an X axis, a Y axis, and a Z axis. In the present specification, a plane parallel to an upper surface of the semiconductor substrate is referred to as an XY plane, and a depth direction of the semiconductor substrate is referred to as the Z axis. It should be noted that in the present specification, in a case where the semiconductor substrate is viewed in a Z axis direction, the view is referred to as a top view.

Each example embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each example embodiment respectively have opposite polarities.

In the present specification, a character N or P specifying a layer or a region means that electrons or holes are majority carriers, respectively. In addition, each of a symbol “+” and a symbol “−” added to N or P represents a layer or a region of a higher doping concentration and a lower doping concentration than that of a layer or a region without the symbol, and a symbol “++” represents a higher doping concentration than “+” while a symbol “−−” represents a lower doping concentration than “−”.

In the present specification, a doping concentration refers to a concentration of a donor or a dopant that has turned into an acceptor. Accordingly, a unit thereof is cm′. In the present specification, a difference in concentration (that is, a net doping concentration) between the donor and the acceptor may be set as the doping concentration. In this case, the doping concentration can be measured by an SR method. In addition, a chemical concentration of the donor and the acceptor may be set as the doping concentration. In this case, the doping concentration can be measured by an SIMS method. If not particularly limited, any of the above may be used as the doping concentration. If not particularly limited, a peak value of a doping concentration distribution in a doping region may be set as the doping concentration in the doping region.

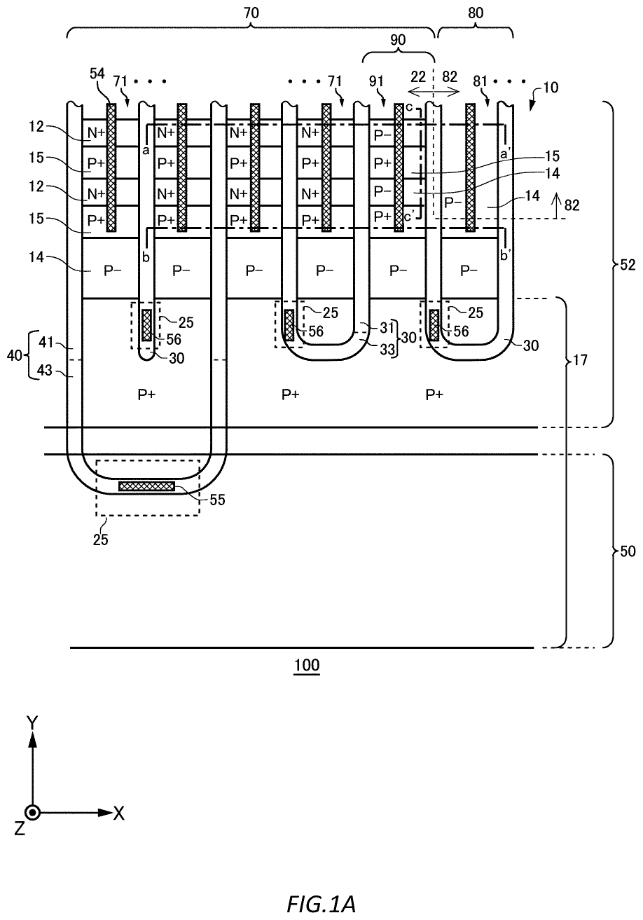

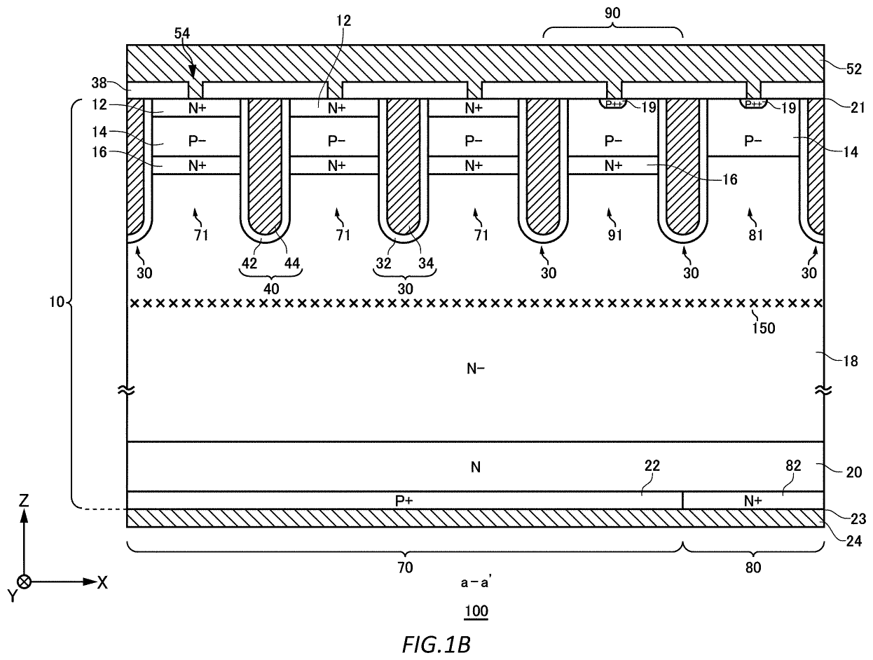

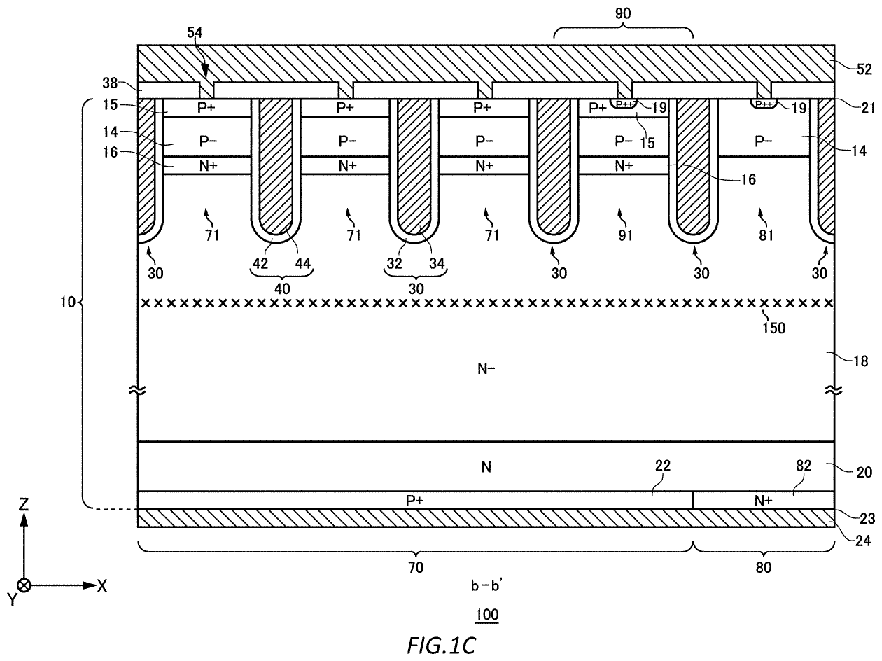

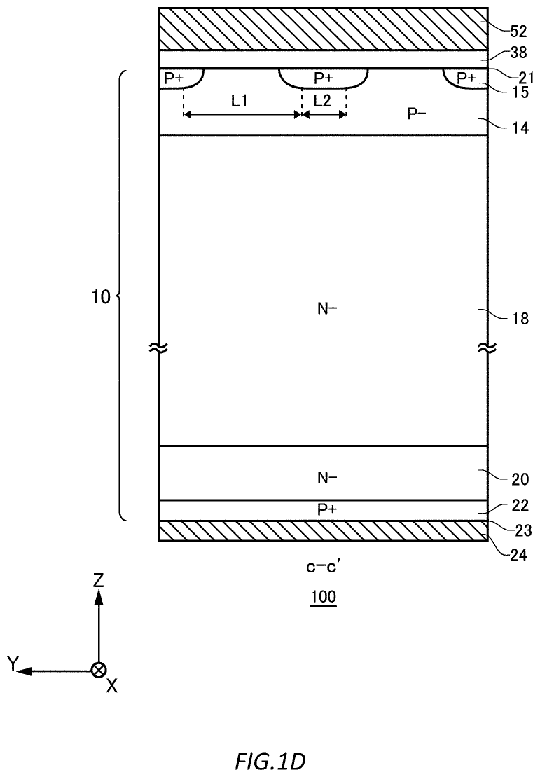

FIG. 1A shows an example of a top plan view of a semiconductor device 100. The semiconductor device 100 of the present example is a semiconductor chip including a transistor portion 70 and a diode portion 80. For example, the semiconductor device 100 is a reverse conducting IGBT (RC-IGBT: Reverse Conducting IGBT).

The transistor portion 70 is a region where a collector region 22 provided on a back surface side of a semiconductor substrate 10 is projected onto an upper surface of the semiconductor substrate 10. The collector region 22 has the second conductivity type. The collector region 22 of the present example is of a P+ type as an example. The transistor portion 70 includes a transistor such as an IGBT. The transistor portion 70 includes a boundary region 90 which is located in a boundary between the transistor portion 70 and the diode portion 80. It should be noted that the boundary region 90 may have a cathode region 82 on the back surface side of the semiconductor substrate 10.

The diode portion 80 is a region where the cathode region 82 provided on the back surface side of the semiconductor substrate 10 is projected onto the upper surface of the semiconductor substrate 10. The cathode region 82 has the first conductivity type. The cathode region 82 of the present example is of an N+ type as an example. The diode portion 80 includes a diode such as a freewheeling diode (FWD: Free Wheel Diode) provided to be adjacent to the transistor portion 70 at the upper surface of the semiconductor substrate 10.

FIG. 1A shows a region around a chip end portion which is an edge side of the semiconductor device 100, and omits another region. For example, an edge termination structure portion may be provided in a region on a negative side of a Y axis direction in the semiconductor device 100 of the present example. The edge termination structure portion relaxes an electric field concentration in an upper surface side of the semiconductor substrate 10. The edge termination structure portion has, for example, a structure of a guard ring, a field plate, a RESURF, and a combination of these. It should be noted that the present example describes an edge on the negative side in the Y axis direction for convenience, but the other edge of the semiconductor device 100 is similar.

The semiconductor substrate 10 may be a silicon substrate, may be a silicon carbide substrate, or may be a nitride semiconductor substrate or the like of gallium nitride or the like. The semiconductor substrate 10 in the present example is the silicon substrate.

The semiconductor device 100 of the present example includes a gate trench portion 40, a dummy trench portion 30, an emitter region 12, a base region 14, a contact region 15, and a well region 17, at a front surface of the semiconductor substrate 10. The semiconductor device 100 of the present example also includes an emitter electrode 52 and a gate metal layer 50 which are provided above the front surface of the semiconductor substrate 10.

The emitter electrode 52 is provided above the gate trench portion 40, the dummy trench portion 30, the emitter region 12, the base region 14, the contact region 15, and the well region 17. In addition, the gate metal layer 50 is provided above the gate trench portion 40 and the well region 17.

The emitter electrode 52 and the gate metal layer 50 are formed of a material containing metal. For example, at least a part of a region of the emitter electrode 52 may be formed of aluminum, or an alloy (for example, an aluminum-silicon alloy, an aluminum-silicon-copper alloy, or the like) which contains aluminum as a main component. At least a part of a region of the gate metal layer 50 may be formed of aluminum, or an alloy (for example, an aluminum-silicon alloy, an aluminum-silicon-copper alloy, or the like) which contains aluminum as a main component. The emitter electrode 52 and the gate metal layer 50 may have barrier metal formed of titanium, a titanium compound, or the like under a region formed of aluminum and the like. The emitter electrode 52 and the gate metal layer 50 are provided separately from each other.

The emitter electrode 52 and the gate metal layer 50 are provided above the semiconductor substrate 10 with an interlayer dielectric film 38 interposed therebetween. The interlayer dielectric film 38 is omitted in FIG. 1A. A contact hole 54, a contact hole 55, and a contact hole 56 are provided to pass through the interlayer dielectric film 38.

The contact hole 55 connects the gate metal layer 50 and a gate conductive portion in the transistor portion 70. In the contact hole 55, a plug formed of tungsten or the like may be formed.

The contact hole 56 connects the emitter electrode 52 and a dummy conductive portion in the dummy trench portion 30. In the contact hole 56, a plug formed of tungsten or the like may be formed.

A connection portion 25 electrically connects a front surface side electrode such as the emitter electrode 52 or the gate metal layer 50, and the semiconductor substrate 10. In an example, the connection portion 25 is provided between the gate metal layer 50 and the gate conductive portion. The connection portion 25 is also provided between the emitter electrode 52 and the dummy conductive portion. The connection portion 25 is formed of a conductive material such as polysilicon doped with impurities. Here, the connection portion 25 is formed of polysilicon (N+) doped with the impurities of the N type. The connection portion 25 is provided above the front surface of the semiconductor substrate 10 via a dielectric film such as an oxide film or the like.

The gate trench portion 40 is arrayed at a predetermined interval along a predetermined array direction (an X axis direction in the present example). The gate trench portion 40 of the present example may have: two extension parts 41 that extend along an extension direction (the Y axis direction in the present example) which is parallel to the front surface of the semiconductor substrate 10 and which is perpendicular to the array direction; and a connection part 43 that connects the two extension parts 41.

At least a part of the connection part 43 may be formed to have a curved shape. By connecting end portions of the two extension parts 41 of the gate trench portion 40, electric field concentrations at the end portions of the extension parts 41 can be relaxed. At the connection part 43 of the gate trench portion 40, the gate metal layer 50 may be connected to the gate conductive portion.

The dummy trench portion 30 is a trench portion electrically connected to the emitter electrode 52. Similarly to the gate trench portion 40, the dummy trench portion 30 is arrayed at a predetermined interval along a predetermined array direction (the X axis direction in the present example). Similarly to the gate trench portion 40, the dummy trench portion 30 of the present example may have, a U shape at the front surface of the semiconductor substrate 10. That is, the dummy trench portion 30 may have two extension parts 31 which extend along the extension direction, and a connection part 33 which connects the two extension parts 31.

The transistor portion 70 of the present example has a structure in which two gate trench portions 40 and three dummy trench portions 30 are repeatedly arrayed. That is, the transistor portion 70 of the present example has the gate trench portion 40 and the dummy trench portion 30 at a ratio of 2:3. For example, the transistor portion 70 has one extension part 31 between two extension parts 41. In addition, the transistor portion 70 has two extension parts 31 adjacent to the gate trench portion 40.

Note that the ratio of the gate trench portion 40 and the dummy trench portion 30 is not limited to that of the present example. The ratio of the gate trench portion 40 and the dummy trench portion 30 may be 1:1, or may be 2:4. In addition, the transistor portion 70 may be entirely provided with the gate trench portion 40 without being provided with the dummy trench portion 30.

The well region 17 is a region of the second conductivity type provided to be closer to a front surface side of the semiconductor substrate 10 than a drift region 18 which will be described below. The well region 17 is an example of a well region provided on the edge side of the semiconductor device 100. The well region 17 is of the P+ type as an example. The well region 17 is formed in a predetermined range from an end portion of an active region on a side on which the gate metal layer 50 is provided. A diffusion depth of the well region 17 may be deeper than depths of the gate trench portion 40 and the dummy trench portion 30. Parts of regions of the gate trench portion 40 and the dummy trench portion 30 in the gate metal layer 50 side are formed in the well region 17. Bottoms of ends of the gate trench portion 40 and the dummy trench portion 30 in the extension direction may be covered with the well region 17.

The contact hole 54 is formed above each region of the emitter region 12 and the contact region 15 in the transistor portion 70. The contact hole 54 is also provided above the base region 14 in the boundary region 90. The contact hole 54 is provided above the contact region 15 in the boundary region 90. The contact hole 54 is provided above the base region 14 in the diode portion 80. None of the contact holes 54 is provided above the well regions 17 provided at both ends in the Y axis direction. In this way, one or more contact holes 54 are formed in an interlayer dielectric film. The one or more contact holes 54 may be provided to extend in the extension direction. It should be noted that a plug region 19 may be provided below the contact hole 54. The plug region 19 will be described below.

The boundary region 90 is a region which is provided in the transistor portion 70 and which is adjacent to the diode portion 80. The boundary region 90 has the contact region 15. The boundary region 90 has the contact region 15, and thus it is possible to extract holes remaining in the diode portion 80 at a time of a turn off operation, and to suppress a destruction due to a latch up. The boundary region 90 in the present example does not have the emitter region 12. This makes it possible to suppress a decrease in latch-up resistance. The boundary region 90 of the present example is constituted by one mesa portion 91 provided to be interposed between two trench portions. By setting the boundary region 90 as the one mesa portion 91, areas of the active regions of the transistor portion 70 and the diode portion 80 can be kept to be wide, and it is possible to suppress a deterioration of an electrical characteristic (for example, a current-voltage characteristic in a forward direction or the like). Note that the boundary region 90 may be configured by three or more trench portions and a plurality of mesa portions 91.

In an example, the trench portion of the boundary region 90 is a dummy trench portion 30. The boundary region 90 of the present example is arranged such that both ends in the X axis direction are the dummy trench portions 30. In addition, the emitter region 12 closest to the boundary region 90 in the array direction is interposed between the dummy trench portions 30. With setting this structure, it is possible to suppress an influence of a fluctuation in gate potential on the electrical characteristic (for example, the current-voltage characteristic in the forward direction or the like).

A mesa portion 71, the mesa portion 91, and a mesa portion 81 are mesa portions provided to be adjacent to the trench portions in a plane parallel to the front surface of the semiconductor substrate 10. The mesa portion is a part of the semiconductor substrate 10 interposed between two trench portions adjacent to each other, and may be a part ranging from the front surface of the semiconductor substrate 10 to a depth of a deepest bottom portion of each trench portion. The extension part of each trench portion may be set as one trench portion. That is, a region interposed between two extension parts may be set as the mesa portion.

The mesa portion 71 is provided to be adjacent to at least one of the dummy trench portion 30 or the gate trench portion 40, in the transistor portion 70. The mesa portion 71 has the well region 17, the emitter region 12, the base region 14, and the contact region 15, at the front surface of the semiconductor substrate 10. In the mesa portion 71, the emitter region 12 and the contact region 15 are alternately provided in the extension direction.

The mesa portion 91 is provided in the boundary region 90. The mesa portion 91 has the base region 14, the contact region 15, and the well region 17, at the front surface of the semiconductor substrate 10. In the mesa portion 91, the base region 14 and the contact region 15 are alternately provided in the extension direction. In this way, in the boundary region 90, the contact regions 15 are provided to be thinned out, and thus it is possible to suppress an excessive hole injection at a time of a diode operation, and to reduce a reverse recovery loss Err, a turn on loss Eon, and a reverse recovery surge voltage.

The mesa portion 81 is provided in a region interposed between the dummy trench portions 30 adjacent to each other, in the diode portion 80. The mesa portion 81 has the base region 14 and the well region 17, at the front surface of the semiconductor substrate 10.

The base region 14 is a region of the second conductivity type provided in the front surface side of the semiconductor substrate 10, in the transistor portion 70 and the diode portion 80. The base region 14 is of a P− type as an example. The base regions 14 may be provided at both end portions of the mesa portion 71 and the mesa portion 91, in the Y axis direction, at the front surface of the semiconductor substrate 10. It should be noted that FIG. 1A shows only one end portion of the base region 14 in the Y axis direction.

The emitter region 12 is a region of the first conductivity type which has a higher doping concentration than that of the drift region 18. The emitter region 12 of the present example is of the N+ type as an example. An example of the dopant of the emitter region 12 is arsenic (As). The emitter region 12 is provided in contact with the gate trench portion 40 at a front surface of the mesa portion 71. The emitter region 12 may be provided to extend in the X axis direction from one trench portion to the other trench portion of two trench portions which interpose the mesa portion 71 therebetween. The emitter region 12 is also provided below the contact hole 54.

In addition, the emitter region 12 may be, or may not be in contact with the dummy trench portion 30. The emitter region 12 in the present example is in contact with the dummy trench portion 30. The emitter region 12 may not be provided in the mesa portion 91.

The contact region 15 is a region of the second conductivity type which has a higher doping concentration than that of the base region 14. The contact region 15 of the present example is of the P+ type as an example. The contact region 15 of the present example is provided at front surfaces of the mesa portion 71 and the mesa portion 91. The contact region 15 may be provided in the X axis direction from one trench portion to the other trench portion of two trench portions which interpose the mesa portion 71 or the mesa portion 91. The contact region 15 may be, or may not be in contact with the gate trench portion 40. In addition, the contact region 15 may be, or may not be in contact with the dummy trench portion 30. In the present example, the contact region 15 is in contact with the dummy trench portion 30 and the gate trench portion 40. The contact region 15 is also provided below the contact hole 54. It should be noted that the contact region 15 may also be provided in the mesa portion 81.

Here, in the transistor portion 70 other than the boundary region 90, the contact region 15 and the emitter region 12 are alternately arranged in the extension direction. In addition, the contact region 15 in the boundary region 90 is provided for a position in the extension direction to correspond to that of the contact region 15 in the transistor portion 70 other than the boundary region 90. The expression of being provided for the position in the extension direction to correspond means that the positions of the contact regions 15 in the extension direction are at least provided to be overlapped. In an example, a mask for implanting the dopant of the contact region 15 is provided to extend in the X axis direction across the plurality of trench portions. This makes it possible to enhance a patterning accuracy even when a width of the mesa portion in the X axis direction is short. In addition, the base region 14 in the boundary region 90 may be provided for a position in the extension direction to correspond to that of the emitter region 12 in the transistor portion 70 other than the boundary region 90.

It should be noted that the plug region 19 is provided to extend in the extension direction without being thinned out, in the contact hole 54. The plug region 19 extends in the extension direction across the base region 14 and the contact region 15, above the base region 14 and the contact region 15 which are alternately arrayed in the extension direction. That is, in the boundary region 90, a length of the plug region 19 which extends in the extension direction is longer than a length of the contact region 15 which extends in the extension direction. In addition, in the boundary region 90, the length of the plug region 19 which extends in the extension direction may be longer than a length of the base region 14 which extends in the extension direction.

FIG. 1B shows an example of a cross section a-a′ of the semiconductor device 100 in FIG. 1A. The cross section a-a′ is an XZ plane passing through the emitter region 12 of the mesa portion 71. The cross section a-a′ of the present example passes through the base region 14 of the mesa portion 91. In the cross section a-a′, the semiconductor device 100 of the present example has the semiconductor substrate 10, the interlayer dielectric film 38, the emitter electrode 52, and a collector electrode 24. The emitter electrode 52 is formed above the semiconductor substrate 10 and the interlayer dielectric film 38.

The drift region 18 is a region of the first conductivity type provided in the semiconductor substrate 10. The drift region 18 of the present example is of an N− type as an example. The drift region 18 may be a remaining region where another doping region is not formed in the semiconductor substrate 10. That is, the doping concentration of the drift region 18 may be the doping concentration of the semiconductor substrate 10.

A buffer region 20 is a region of the first conductivity type provided below the drift region 18. The buffer region 20 in the present example is of the N type as an example. The doping concentration of the buffer region 20 is higher than the doping concentration of the drift region 18. The buffer region 20 may function as a field stop layer which prevents a depletion layer expanding from a lower surface side of the base region 14 from reaching the collector region 22 of the second conductivity type and the cathode region 82 of the first conductivity type.

The collector region 22 is provided below the buffer region 20 in the transistor portion 70. The cathode region 82 is provided below the buffer region 20 in the diode portion 80. A boundary between the collector region 22 and the cathode region 82 is the boundary between the transistor portion 70 and the diode portion 80.

The collector electrode 24 is formed on a back surface 23 of the semiconductor substrate 10. The collector electrode 24 is formed of a conductive material such as metal.

The base region 14 is a region of the second conductivity type which is provided above the drift region 18 in the mesa portion 71, the mesa portion 91, and the mesa portion 81. The base region 14 is provided in contact with the gate trench portion 40. The base region 14 may be provided in contact with the dummy trench portion 30.

The emitter region 12 is provided between the base region 14 and the front surface 21, in the mesa portion 71. The emitter region 12 is provided in contact with the gate trench portion 40. The emitter region 12 may be, or may not be in contact with the dummy trench portion 30. It should be noted that the emitter region 12 may not be provided in the mesa portion 91.

The plug region 19 is a region of the second conductivity type which has a higher doping concentration than those of the base region 14 and the contact region 15. The plug region 19 of the present example is of a P++ type as an example. The plug region 19 in the present example is provided at the front surface 21. In the cross section a-a′, the plug region 19 is provided above the base region 14 in the mesa portion 81 and the mesa portion 91. The plug region 19 in the present example is in contact with the base region 14. In addition, the plug region 19 is spaced apart from the adjacent trench portion. The plug region 19 may be provided to extend in the Y axis direction along the contact hole 54 in the mesa portion 91 and the mesa portion 81. The plug regions 19 of the mesa portion 81 and the mesa portion 91 in the present example have doping concentrations which are the same as each other, but may have doping concentrations which are different from each other.

An accumulation region 16 is a region of the first conductivity type which is provided to be closer to a front surface 21 side of the semiconductor substrate 10 than the drift region 18. The accumulation region 16 of the present example is of the N+ type as an example. The accumulation region 16 is provided in the transistor portion 70. The accumulation regions 16 of the present example are provided in both of the boundary region 90 and the transistor portion 70 other than the boundary region 90. The transistor portion 70 other than the boundary region 90 is a region where the mesa portion 71 is formed.

In addition, the accumulation region 16 is provided in contact with the gate trench portion 40. The accumulation region 16 may be, or may not be in contact with the dummy trench portion 30. The doping concentration of the accumulation region 16 is higher than the doping concentration of the drift region 18. A dose amount of ion implantations of the accumulation region 16 may be 1E12 cm′ or more and 1E13 cm-2 or less. In addition, the dose amount of the ion implantations of the accumulation region 16 may be 3E12 cm-2 or more and 6E12 cm′ or less. Providing the accumulation region 16 makes it possible to enhance a carrier injection enhancement effect (IE effect) to reduce an ON voltage of the transistor portion 70. It should be noted that the character E means a power of 10, and for example, 1E12 cm-2 means 1×1012 cm′.

One or more gate trench portions 40 and one or more dummy trench portions 30 are provided at the front surface 21. Each trench portion is provided from the front surface 21 to the drift region 18. In a region provided with at least any of the emitter region 12, the base region 14, the contact region 15, or the accumulation region 16, each trench portion also passes through these regions to reach the drift region 18. A structure in which the trench portion passes through the doping region is not limited to a structure in which the semiconductor substrate is manufactured in order of forming the doping region and then forming the trench portion. A structure in which the trench portion is formed and then the doping region is formed between the trench portions is also included in the structure in which the trench portion passes through the doping region.

The gate trench portion 40 has a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed on an inner side further than the gate dielectric film 42 in the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 at the front surface 21.

The gate conductive portion 44 includes a region facing the base region 14 which is adjacent on a mesa portion 71 side with the gate dielectric film 42 interposed therebetween in the depth direction of the semiconductor substrate 10. When a predetermined voltage is applied to the gate conductive portion 44, a channel is formed by an inversion layer of electrons on a surface layer in the base region 14 at an interface in contact with the gate trench.

The dummy trench portion 30 may have the same structure as that of the gate trench portion 40. The dummy trench portion 30 has a dummy trench, a dummy dielectric film 32, and a dummy conductive portion 34 which are formed in the front surface 21 side. The dummy dielectric film 32 is formed to cover an inner wall of the dummy trench. The dummy conductive portion 34 is formed in the dummy trench, and is formed on an inner side further than the dummy dielectric film 32. The dummy dielectric film 32 insulates the dummy conductive portion 34 from the semiconductor substrate 10. The dummy trench portion 30 is covered with the interlayer dielectric film 38 at the front surface 21.

The interlayer dielectric film 38 is provided on the front surface 21. The emitter electrode 52 is provided above the interlayer dielectric film 38. The interlayer dielectric film 38 is provided with one or more contact holes 54 to electrically connect the emitter electrode 52 and the semiconductor substrate 10. Similarly, the contact hole 55 and the contact hole 56 may also be provided to pass through the interlayer dielectric film 38.

A lifetime control region 150 is a region where a lifetime killer is intentionally formed by implanting the impurities into the semiconductor substrate 10, or the like. The lifetime killer is a recombination center for a carrier. The lifetime killer may be a crystal defect. For example, the lifetime killer may be a vacancy, a divacancy, a complex defect of these with elements constituting the semiconductor substrate 10, or a dislocation. In addition, the lifetime killer may be a rare gas element such as helium and neon, a metal element such as platinum, or the like. The lifetime control region 150 can be formed by implanting helium or the like into the semiconductor substrate 10.

The lifetime control region 150 is provided in the front surface 21 side of the semiconductor substrate 10. The lifetime control regions 150 are provided in both of the transistor portion 70 and the diode portion 80. The lifetime control region 150 may be formed by implanting the impurities from the front surface 21 side, or may be formed by implanting the impurities from a back surface 23 side.

The lifetime control region 150 is provided from the diode portion 80, across the boundary region 90, to the transistor portion 70 provided with the emitter region 12, in the array direction. The lifetime control region 150 of the present example is provided over the entire surface of the semiconductor substrate 10 in the top view. This makes it possible for the lifetime control region 150 to be formed without using the mask. The dose amount of the impurities to form the lifetime control region 150 may be 0.5E10 cm-2 or more and 1E13 cm-2 or less. In addition, the dose amount of the impurities to form the lifetime control region 150 may be 5E10 cm-2 or more and 5E11 cm′ or less.

In addition, the lifetime control region 150 of the present example is formed by the implantation from the back surface 23 side. For example, the lifetime control region 150 is formed by radiating helium from the back surface 23 side. This makes it possible to avoid an influence on the front surface 21 side of the semiconductor device 100. Here, whether the lifetime control region 150 is formed by the implantation from the front surface 21 side, or by the implantation from the back surface 23 side can be determined by acquiring a state of the front surface 21 side by the SR method or a measurement of a leakage current.

The collector region 22 in the present example is provided on the back surface 23 below the boundary region 90. The boundary between the collector region 22 and the cathode region 82 is located at the boundary between the transistor portion 70 and the diode portion 80.

FIG. 1C shows an example of a cross section b-b′ of the semiconductor device 100 in FIG. 1A. The cross section b-b′ is the XZ plane passing through the contact region 15 in the mesa portion 71. The cross section b-b′ of the present example passes through the contact region 15 in the mesa portion 91 as well.

The mesa portion 71 has the base region 14, the contact region 15, and the accumulation region 16. The mesa portion 91 has the base region 14, the contact region 15, the accumulation region 16, and the plug region 19. In the cross section b-b′, the mesa portion 91 has the plug region 19, which is a difference from the mesa portion 71. The mesa portion 81 has the base region 14, the accumulation region 16, and the plug region 19, similarly to the cross section a-a′.

The contact region 15 is provided above the base region 14 in the mesa portion 91. The contact region 15 is provided in contact with the dummy trench portion 30 in the mesa portion 91.

The plug region 19 is provided above the contact region 15 of the mesa portion 91 in the cross section b-b′. The plug region 19 of the present example is in contact with the contact region 15. The plug region 19 is provided in the mesa portion 91 in both of the cross section ‘a-a’ and the cross section b-b′. That is, the plug region 19 is provided to extend in the extension direction at the front surface 21.

The lifetime control regions 150 are provided in both of the transistor portion 70 and the diode portion 80 similarly to the case of the cross section a-a′. The semiconductor device 100 of the present example includes the lifetime control regions 150 in both of the transistor portion 70 and the diode portion 80, and thus a hole omission is uniform at the time of the turn off, and a carrier balance of the transistor portion 70 and the diode portion 80 is improved.

FIG. 1D shows an example of a cross section c-c′ of the semiconductor device 100 in FIG. 1A. The cross section c-c′ is a cross section YZ of the mesa portion 91.

In the mesa portion 91, the base region 14 and the contact region 15 are exposed to the front surface 21. The base region 14 and the contact region 15 are alternately arrayed at the front surface 21 at a predetermined thinning rate. The thinning rate is indicated by L1/(L1+L2). That is, the thinning rate indicates a rate of the base region which is exposed on the front surface 21 in the boundary region 90.

The length L1 is a width, in the Y axis direction, between bottoms of the contact regions 15 in the front surface 21 side. The length L1 may be 2.2 μm or more and 30 μm or less. For example, length L1 is 2.2 μm. The length L2 is a width, in the Y axis direction, of a bottom of the contact region 15 in the front surface 21 side. The length L2 may be 0.5 μm or more and 5.0 μm or less. For example, the length L2 is 0.6 μm. The length L2 may be greater than the length L1. It should be noted that the bottom of the contact region 15 is a part in which a boundary between the base region 14 and the contact region 15 is mostly flat in the Y axis direction.

In the semiconductor device 100 of the present example, the base region 14 and the contact region 15 are alternately provided at a predetermined thinning rate in the boundary region 90, and thus it is possible to reduce a reverse recovery current Irp, and to reduce the reverse recovery loss Err and a surge voltage. In addition, the semiconductor device 100 can suppress an increase in contact resistance and suppress the destruction at times of the turn off and the reverse recovery. Further, the semiconductor device 100 can suppress the decrease in latch-up resistance without being provided with the emitter region 12 in the boundary region 90. This makes it possible for the semiconductor device 100 to improve a trade-off characteristic of a diode forward voltage Vf and the reverse recovery loss Err, to reduce the reverse recovery surge voltage, and to suppress a variation in SW resistance.

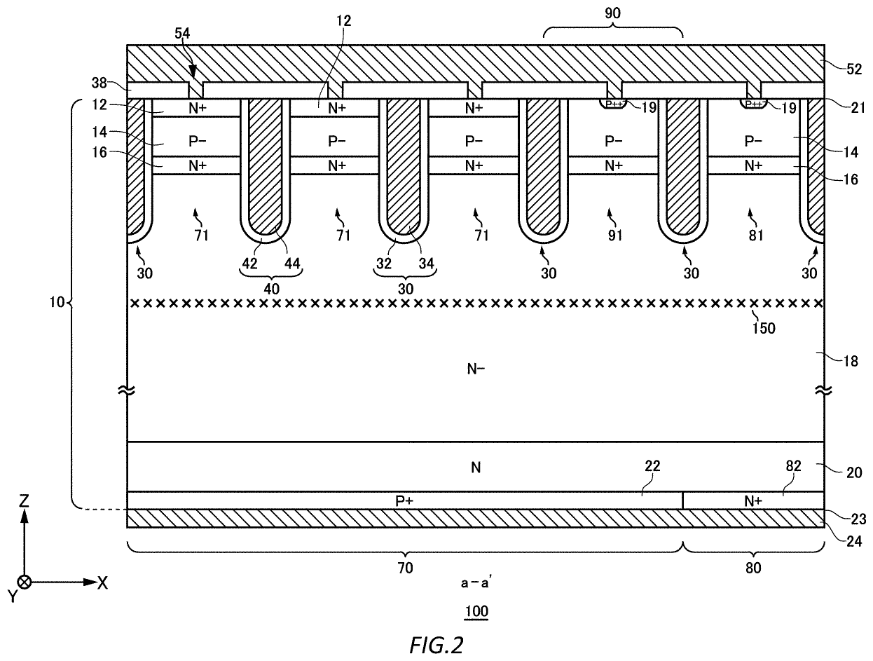

FIG. 2 shows a modification example of the semiconductor device 100. The present example shows an example of the cross section a-a′ in FIG. 1A. The semiconductor device 100 of the present example includes the accumulation regions 16 in both of the transistor portion 70 and the diode portion 80, which is a difference from the example embodiment of FIG. 1B. The semiconductor device 100 of the present example may be the same as the example embodiment of FIG. 1B other than the point of difference from the example embodiment of FIG. 1B.

The accumulation region 16 of the present example is provided over the entire surfaces of the transistor portion 70 and the diode portion 80. This makes it possible for the semiconductor device 100 to avoid an influence of a mask deviation of the accumulation region 16. The mesa portion 81 includes the base region 14, the accumulation region 16, and the plug region 19. The accumulation region 16 is provided between the base region 14 and the drift region 18. The doping concentrations of the accumulation regions 16 in the transistor portion 70 and the diode portion 80 may be the same as each other.

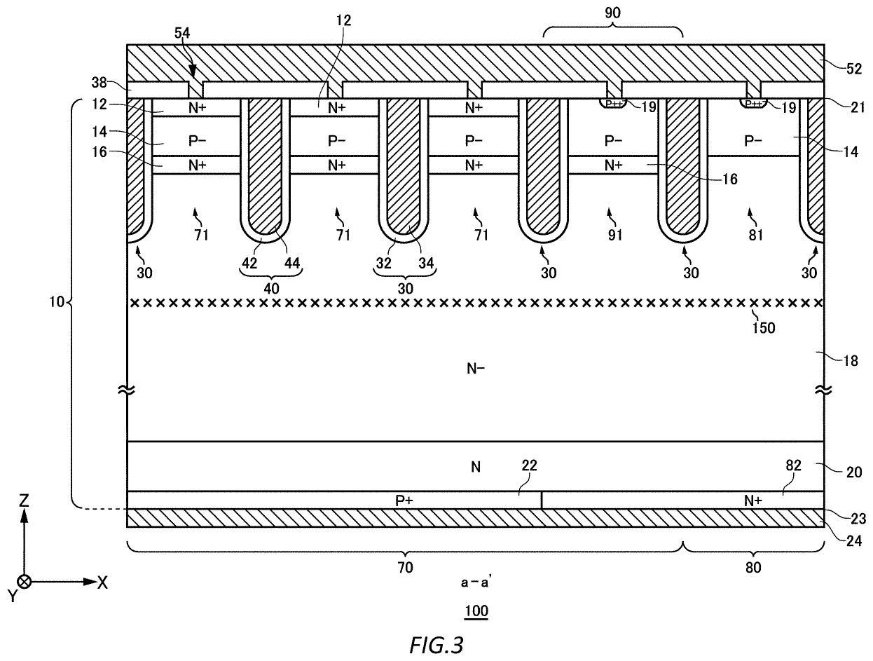

FIG. 3 shows a modification example of the semiconductor device 100. The present example shows an example of the cross section a-a′ in FIG. 1A. The semiconductor device 100 of the present example includes the cathode region 82 below the boundary region 90, which is a difference from the example embodiment of FIG. 1B. The semiconductor device 100 of the present example may be the same as the example embodiment of FIG. 1B other than the point of difference from the example embodiment of FIG. 1B.

The cathode region 82 in the present example is provided on the back surface 23 below the boundary region 90. The boundary between collector region 22 and cathode region 82 is located at a boundary between the boundary region 90 and the transistor portion 70 other than boundary region 90. The boundary between the collector region 22 and the cathode region 82 in the present example is provided below the dummy trench portion 30 adjacent to the mesa portion 91, but is not limited to this. The boundary between the collector region 22 and the cathode region 82 may be located below the mesa portion 91.

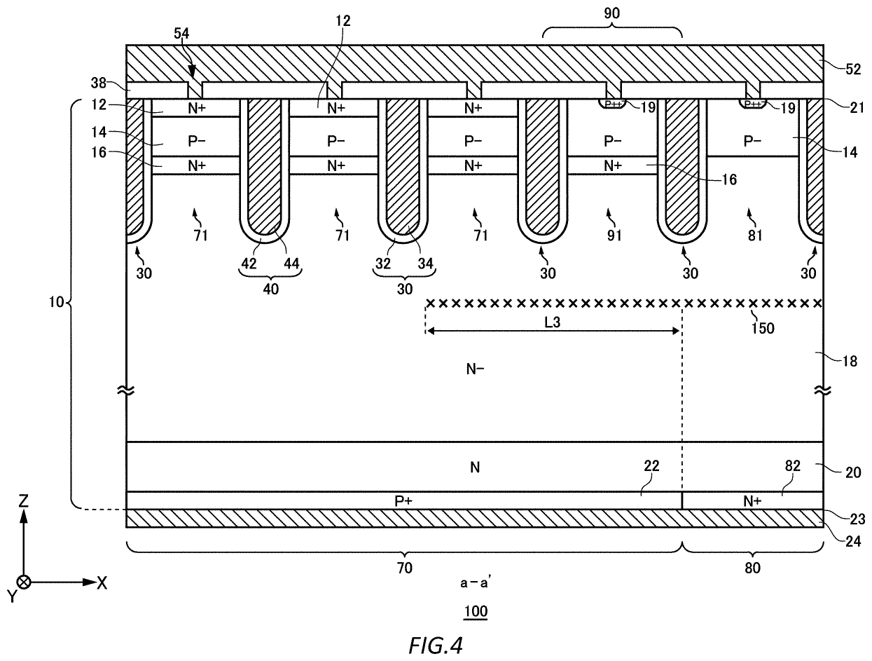

FIG. 4 shows a modification example of the semiconductor device 100. The present example shows an example of the cross section a-a′ in FIG. 1A. The semiconductor device 100 of the present example is provided with the lifetime control region 150 not over the entire surface of the semiconductor substrate 10 but at a part thereof, which is a difference from the example embodiment of FIG. 1B. The semiconductor device 100 of the present example may be the same as the example embodiment of FIG. 1B other than the point of difference from the example embodiment of FIG. 1B.

The lifetime control region 150 is provided from the diode portion 80, across the boundary region 90, to the transistor portion 70 provided with the emitter region 12, in the array direction. The lifetime control region 150 of the present example is provided over the entire surface of the diode portion 80 and a part of the transistor portion 70. A length L3 is a length in the array direction from the boundary between the collector region 22 and the cathode region 82 to an end portion of the lifetime control region 150. The length L3 may be the same as a film thickness of the semiconductor substrate 10, or may be greater than the film thickness of the semiconductor substrate 10. By appropriately setting the length L3, it is possible to suppress the carrier injection.

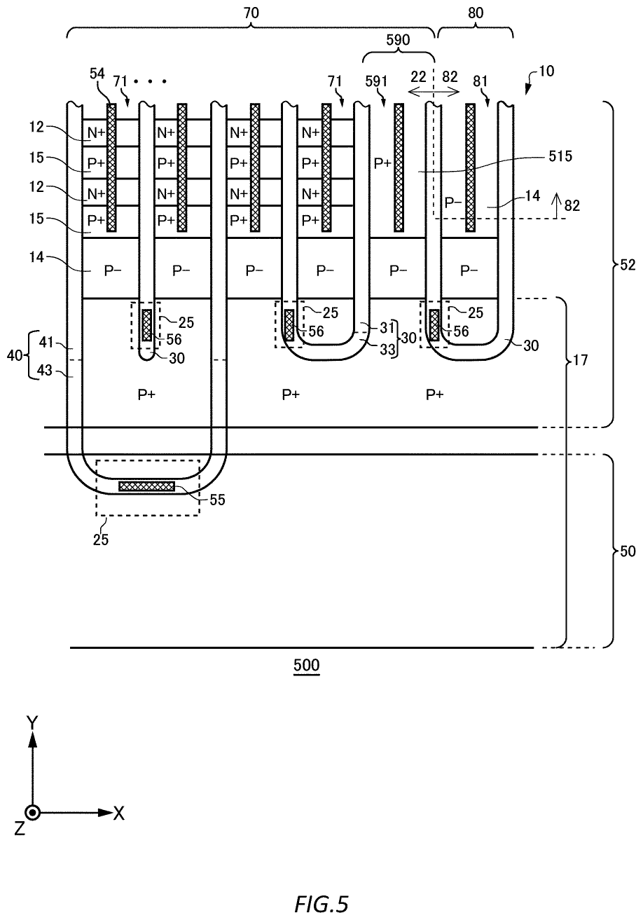

FIG. 5 shows a semiconductor device 500 of a comparison example. The semiconductor device 500 includes a boundary region 590. A mesa portion 591 of the boundary region 590 has a contact region 515 exposed to the front surface of the semiconductor substrate 10. In the mesa portion 591 of the present example, the contact region 515 is provided over an entire surface of a region interposed between the base regions 14 at both ends in the Y axis direction. That is, in the mesa portion 591, the contact region 515 and the base region 14 are not provided alternately.

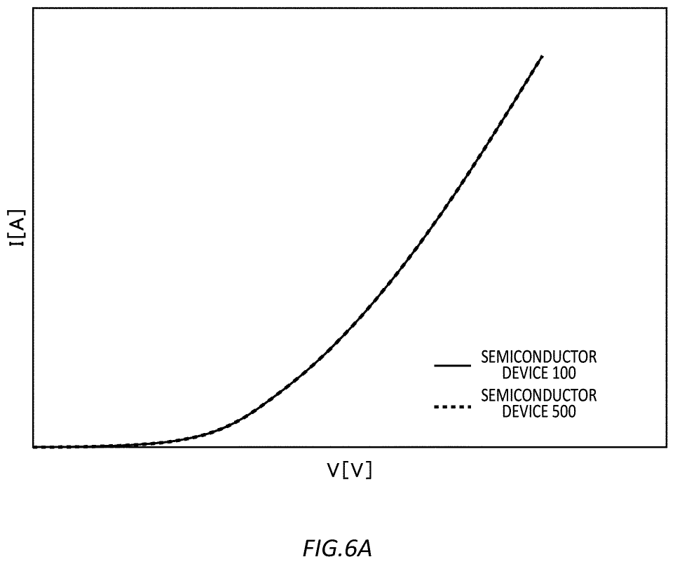

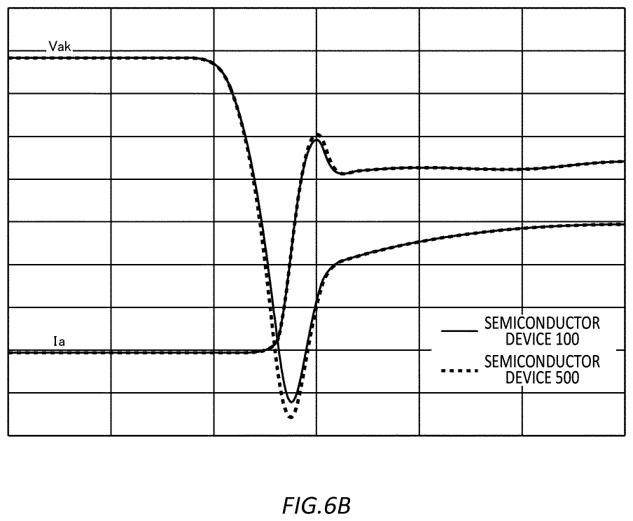

FIG. 6A shows examples of IV characteristics of the semiconductor device 100 and the semiconductor device 500. There is no significant difference in IV characteristic between the semiconductor device 100 and the semiconductor device 500.

FIG. 6B shows examples of reverse recovery characteristics of the semiconductor device 100 and the semiconductor device 500. When graphs at the time of the reverse recovery are compared, it can be seen that the semiconductor device 100 has a lower reverse recovery loss than that of the semiconductor device 500. In this way, the semiconductor device 100 can enhance the reverse recovery characteristic without significantly affecting the IV characteristic.

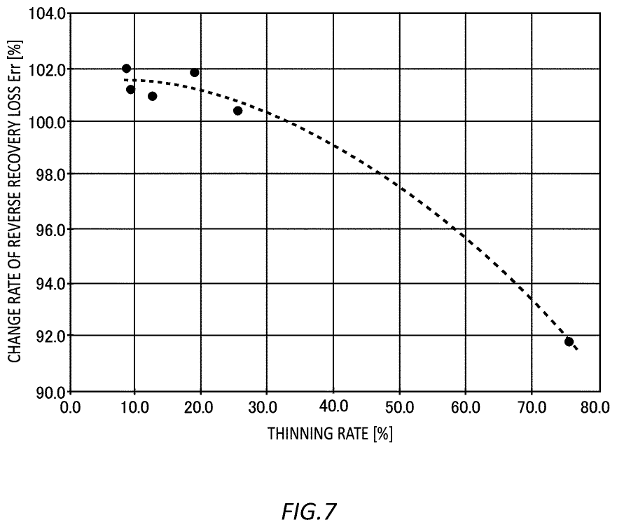

FIG. 7 shows a relationship between a thinning rate [%] and a change rate [%] of a reverse recovery loss Err. The reverse recovery loss Err decreases as the thinning rate increases. The thinning rate may be 20.0% or more, or may be 30.0% or more. The thinning rate may be 80.0% or less, may be 70.0% or less, or may be 60.0% or less. By appropriately setting the thinning rate, the semiconductor device 100 of the present example can reduce the reverse recovery loss Err while suppressing the latch-up destruction.

While the present invention has been described with the embodiments, the technical scope of the present invention is not limited to the above described embodiments. It is apparent to persons skilled in the art that various alterations and improvements can be added to the above-described embodiments. It is also apparent from the description of the claims that embodiments added with such alterations or improvements can be included in the technical scope of the present invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

### EXPLANATION OF REFERENCES

10: semiconductor substrate, 12: emitter region, 14: base region, 15: contact region, 16: accumulation region, 17: well region, 18: drift region, 19: plug region, 21: front surface, 22: collector region, 23: back surface, 24: collector electrode, 25: connection portion, 30: dummy trench portion, 38: interlayer dielectric film, 40: gate trench portion, 41: extension part, 43: connection part, 50: gate metal layer, 52: emitter electrode, 54: contact hole, 55: contact hole, 56: contact hole, 70: transistor portion, 71: mesa portion, 80: diode portion, 81: mesa portion, 82: cathode region, 90: boundary region, 91: mesa portion, 100: semiconductor device, 150: lifetime control region, 500: semiconductor device, 515: contact region, 590: boundary region, 591: mesa portion.

What is claimed is:

1. A semiconductor device that includes a transistor portion and a diode portion, the semiconductor device comprising:
a drift region of a first conductivity type provided in a semiconductor substrate;
a base region of a second conductivity type provided above the drift region;
an emitter region of the first conductivity type which is provided above the base region and which has a doping concentration higher than that of the drift region;
a contact region of the second conductivity type which is provided above the base region and which has a doping concentration higher than that of the base region; and
a plurality of trench portions provided at a front surface of the semiconductor substrate, wherein
the transistor portion has a boundary region provided to be adjacent to the diode portion,
a lifetime control region is provided from the diode portion, across the boundary region, to the transistor portion provided with the emitter region, in an array direction of the plurality of trench portions,
the boundary region has a plug region of the second conductivity type which is provided to extend in an extension direction of the plurality of trench portions and which has a doping concentration higher than that of the base region, and
the contact region and the base region are alternately arranged in the extension direction, at the front surface in the boundary region.

2. The semiconductor device according to claim 1, wherein
the boundary region is constituted by one mesa portion provided to be interposed between two trench portions among the plurality of trench portions.

3. The semiconductor device according to claim 1, wherein
in the transistor portion other than the boundary region, the contact region and the emitter region are alternately arranged in the extension direction, and
the contact region in the boundary region is provided for a position in the extension direction to correspond to that of the contact region in the transistor portion other than the boundary region.

4. The semiconductor device according to claim 1, wherein
in the boundary region, a thinning rate which is a rate of the base region exposed on the front surface, is 30% or more and 80% or less.

5. The semiconductor device according to claim 1, wherein
in the boundary region, a length of the plug region which extends in the extension direction is longer than a length of the contact region which extends in the extension direction.

6. The semiconductor device according to claim 1, wherein
the diode portion has the plug region, and
the plug region of the boundary region has a same doping concentration as the plug region of the diode portion.

7. The semiconductor device according to claim 1, wherein
The plurality of trench portions in the boundary region are dummy trench portions.

8. The semiconductor device according to claim 1, wherein
the emitter region closest to the boundary region in the array direction is interposed between dummy trench portions.

9. The semiconductor device according to claim 2, wherein
the emitter region closest to the boundary region in the array direction is interposed between dummy trench portions.

10. The semiconductor device according to claim 1, wherein
the boundary region is not provided with the emitter region.

11. The semiconductor device according to claim 2, wherein
the boundary region is not provided with the emitter region.

12. The semiconductor device according to claim 1, comprising:
a collector region of the second conductivity type provided on a back surface of the semiconductor substrate, below the boundary region.

13. The semiconductor device according to claim 2, comprising:
a collector region of the second conductivity type provided on a back surface of the semiconductor substrate, below the boundary region.

14. The semiconductor device according to claim 1, comprising:
a cathode region of the first conductivity type provided on a back surface of the semiconductor substrate, below the boundary region.

15. The semiconductor device according to claim 2, comprising:
a cathode region of the first conductivity type provided on a back surface of the semiconductor substrate, below the boundary region.

16. The semiconductor device according to claim 1, wherein
the lifetime control region is provided over an entire surface of the semiconductor substrate in a top view.

17. The semiconductor device according to claim 2, wherein
the lifetime control region is provided over an entire surface of the semiconductor substrate in a top view.

18. The semiconductor device according to claim 1, wherein
the transistor portion has an accumulation region of the first conductivity type which is provided above the drift region and which has a doping concentration higher than that of the drift region; and
the accumulation regions are provided in both of the boundary region and the transistor portion other than the boundary region.

19. The semiconductor device according to claim 18, wherein
the accumulation regions are provided in both of the transistor portion and the diode portion.

20. The semiconductor device according to claim 2, wherein
the transistor portion has an accumulation region of the first conductivity type which is provided above the drift region and which has a doping concentration higher than that of the drift region; and
the accumulation regions are provided in both of the boundary region and the transistor portion other than the boundary region.
